(19) United States
(12) Patent Application Publication
(10) Pub. No.: US 2026/0082622 A1
(43) Pub. Date: Mar. 19, 2026

(54) LDMOS TRANSISTOR

(71) Applicant: Silergy Semiconductor Technology (Hangzhou) LTD, Hangzhou (CN)

(72) Inventors: Hui Yu, Hangzhou (CN); Jun Cai, Hangzhou (CN)

(21) Appl. No.: 19/320,159

(22) Filed: Sep. 5, 2025

(30) Foreign Application Priority Data
Sep. 14, 2024 (CN) 202411297296.8

(51) Int. Cl. H10D 30/65; H10D 62/10; H10D 64/00

(52) U.S. Cl. CPC H10D 30/65; H10D 62/109; H10D 62/116; H10D 64/111

(57) ABSTRACT

An LDMOS transistor can include: a semiconductor region; a body region of a second doping type, wherein the body region extends from an upper surface of the semiconductor region to an interior of the semiconductor region; a source region of a first doping type and a body contact region of the second doping type, where the source region extends from an upper surface of the body region to an interior of the body region; a drain region of the first doping type, wherein the drain region is located in the semiconductor region; a source electrode that is in contact with the body contact region and the source region; and where a junction depth of the body contact region is greater than a junction depth of the source region.

### RELATED APPLICATIONS

This application claims the benefit of Chinese Patent Application No. 202411297296.8, filed on Sep. 14, 2024, which is incorporated herein by reference in its entirety.

### FIELD OF THE INVENTION

The present invention generally relates to the field of semiconductor technology, and more particularly to semiconductor devices including LDMOS transistors.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

FIG. 1 is a cross-sectional view of a first example LDMOS transistor, in accordance with embodiments of the present invention.

FIG. 2 is a cross-sectional view of a second example LDMOS transistor, in accordance with embodiments of the present invention.

FIG. 3 is a cross-sectional view of a third example LDMOS transistor, in accordance with embodiments of the present invention.

FIG. 4 is a cross-sectional view of a fourth example LDMOS transistor, in accordance with embodiments of the present invention.

FIG. 5 is a cross-sectional view of a fifth example LDMOS transistor, in accordance with embodiments of the present invention.

FIG. 6 is a cross-sectional view of a sixth example LDMOS transistor, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Further, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die can be mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

Laterally-diffused metal-oxide-semiconductor (LDMOS) transistors are widely used in power integrated circuits as common power devices due to their high breakdown voltage and compatibility with CMOS processes. However, with the increase in integration density and the reduction of process linewidth, the turn-on of parasitic transistors within the LDMOS has become important mechanism for a device failure, greatly reducing the reliability of the device.

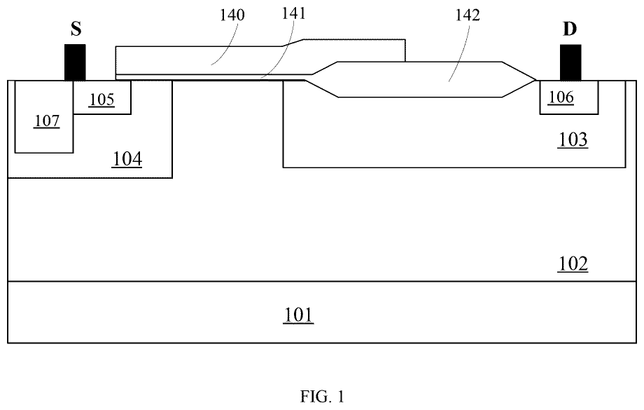

Referring now to FIG. 1, shown is a cross-sectional view of a first example LDMOS transistor, in accordance with embodiments of the present invention. In this particular example, the LDMOS transistor can include semiconductor region 102, body region 104 of a second doping type extending from an upper surface of semiconductor region 102 to an interior of the semiconductor region, a source region 105 of a first doping type and a body contact region 107 of the second doping type extending from an upper surface of body region 104 to an interior thereof, drain region 106 of the first doping type located in semiconductor region 102, and source electrode S being in contact with body contact region 107 and source region 105 and located on upper surfaces of body contact region 107 and source region 105. For example, a junction depth of body contact region 107 can be greater than a junction depth of source region 105. In one example, body contact region 107 may be in contact with a side surface of source region 105.

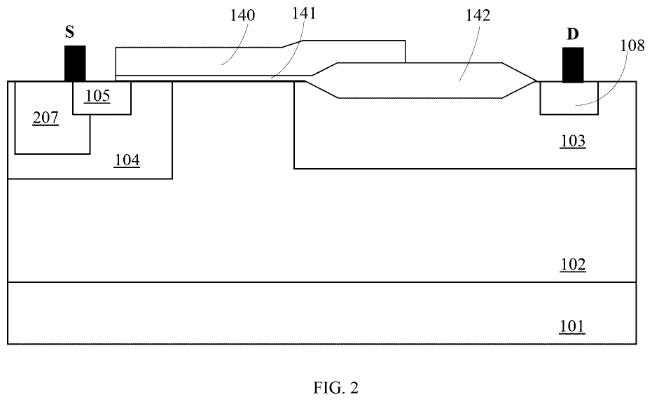

Referring now to FIG. 2, shown is a cross-sectional view of a second example LDMOS transistor, in accordance with embodiments of the present invention. In this particular example, body contact region 207 can surround at least a portion of a lower surface of source region 105. In another example, body contact region 207 may also surround the entire lower surface of source region 105.

The LDMOS transistor can also include drift region 103 of the first doping type, gate dielectric layer 141 close to source region 105 and located on the upper surface of semiconductor region 102, voltage-blocking layer 142 close to drain region 106 and located on semiconductor region 102, and gate conductor 140 located on at least the gate dielectric layer. For example, body region 104 can extend to a bottom of a portion of the gate dielectric layer 141, drift region 103 can at least extend to a bottom of voltage-blocking layer 142, drain region 106 may be located in drift region 103 and on a side of voltage-blocking layer 142 away from the gate dielectric layer 141, and gate conductor 140 can further extend to voltage-blocking layer 142.

For example, the LDMOS transistor can also include substrate 101. The substrate can be of the second doping type, and the semiconductor region may be of the first doping type. In another example, the semiconductor region may also be of the second doping type. In this case, the body region and the drift region can be arranged to be in contact with each other. In addition, an epitaxial layer or a buried layer may also be included between the substrate and the semiconductor region. The base resistance of the parasitic transistor (e.g., source region 105/body region 104/semiconductor region 102/drift region 103) can be reduced by setting the junction depth of the body contact region to be greater than the junction depth of the source region. In this way, the influence of the parasitic transistor on the robustness of the LDMOS transistor can be reduced.

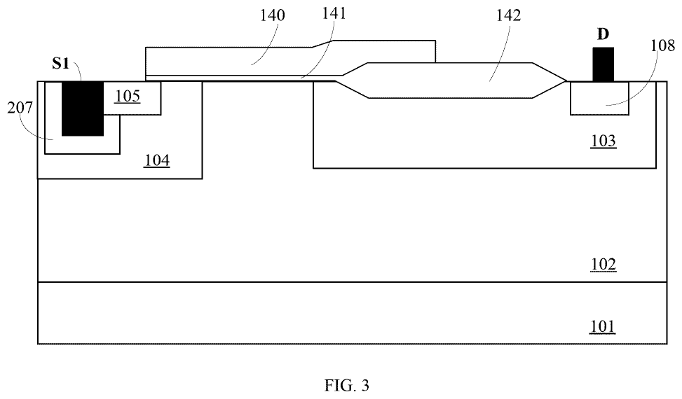

Referring now to FIG. 3, shown is a cross-sectional view of a third example LDMOS transistor, in accordance with embodiments of the present invention. In this particular example, body contact region 207 can extend from the upper surface of body region 104 to an interior of body region 104. Also, body contact region 207 may extend laterally to a bottom of source region 105 to partially surround the lower surface of source region 105. Source electrode S1 may extend from the upper surface of body contact region 207 to the interior thereof, and source electrode S1 can be in contact with a side surface of source region 105. Further, the lower surface of source electrode S1 can be lower than the lower surface of source region 105, and a width of source electrode S1 along a direction from the source region to the drain region may be less than a width of body contact region 207. For example, source electrode S1 can include a trench located in body contact region 207, and a conductive material filled in the trench.

The setting of the body contact region and the source electrode in particular embodiments can facilitate the accumulated charge in the base region of the surface parasitic transistor to be drawn away by the source electrode in the body contact region. This can be beneficial to improving the high current capability and robustness of the LDMOS transistor and enhancing the reverse recovery capability of the transistor.

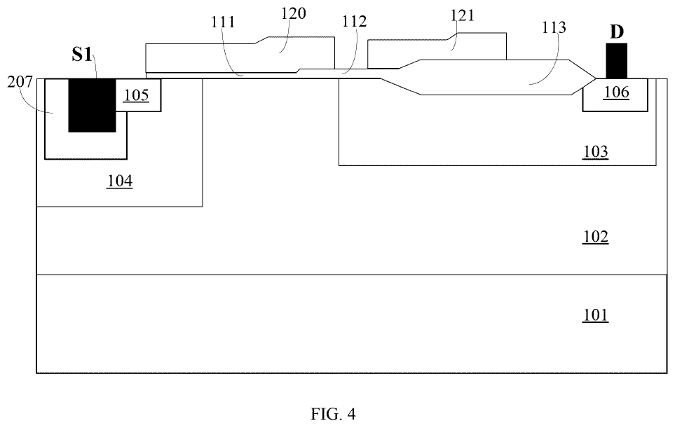

Referring now to FIG. 4, shown is a cross-sectional view of a fourth example LDMOS transistor, in accordance with embodiments of the present invention. In this particular example, the LDMOS transistor can include semiconductor region 102, source region 105 of the first doping type and drain region 106 of the first doping type located in semiconductor region 102, gate dielectric layer 111 close to source region 105 and located on the upper surface of semiconductor region 102, voltage-blocking layer 113 close to the drain region and located on the upper surface of the semiconductor region and protruding toward the interior of semiconductor region 102, and buffer field plate 112 disposed between gate dielectric layer 111 and voltage-blocking layer 113 and located on the upper surface of semiconductor region 102

For example, a thickness of voltage-blocking layer 113 can be greater than the thickness of buffer field plate 112, and the thickness of buffer field plate 112 may be greater than a thickness of gate dielectric layer 111. For example, a length of gate dielectric layer 111 can be less than a length of voltage-blocking layer 113, and a length of buffer field plate 112 may be less than the length of voltage-blocking layer 113. The length and the thickness of buffer field plate 112 and the length and the thickness of voltage-blocking layer 113 can be adjusted according to particular requirements of an applied voltage and ultimate optimization of specific on-resistance Rsp.

As an example, a lower surface of voltage-blocking layer 113 can be lower than a lower surface of buffer field plate 112, an upper surface of buffer field plate 112 may be higher than an upper surface of gate dielectric layer 111, and an upper surface of voltage-blocking layer 113 can be higher than the upper surface of buffer field plate 112. The lower surface of buffer field plate 112 and the lower surface of gate dielectric layer 111 may be coplanar or substantially coplanar. When gate dielectric layer 111 and buffer field plate 112 are both formed by depositing a dielectric layer, the lower surface of buffer field plate 112 and the lower surface of gate dielectric layer 111 can be located on the same plane. When gate dielectric layer 111 and buffer field plate 112 are both formed by thermal oxidation growth, the lower surface of buffer field plate 112 may be slightly lower than the lower surface of gate dielectric layer 111.

In one example, buffer field plate 112 may have a uniform thickness. In another example, the buffer field plate can be arranged along the direction from the source region to the drain region, and the thickness of the buffer field plate can gradually increase. For example, voltage-blocking layer 113 can be shaped like a bird's beak, and may be formed by a local oxidation of silicon (LOCOS) process. The thickness of voltage-blocking layer 113 can be uniform except for the bird's beak portion. In another example, voltage-blocking layer 113 may be formed by a process of depositing a dielectric layer. In this case, the lower surface of voltage-blocking layer 113 and the lower surface of buffer field plate 112 can be substantially coplanar. In yet another example, the thickness of voltage-blocking layer 113 can increase along the direction from the source region to the drain region.

For example, the thickness of the gate dielectric layer can be set to be in a range of from 0.95 nm to 9.5 nm, which can allow the gate dielectric layer to be formed synchronously with a gate oxide of a CMOS device. The thickness of the buffer field plate can be set to be in a range of from 4 nm to 40 nm, and the thickness of the voltage-blocking layer can be set to be in a range of from 25 nm to 350 nm. Both the buffer field plate and the voltage-blocking layer can be formed by a thermal oxidation growth process or a deposition process, as just two examples.

The LDMOS transistor can also include gate conductor 120 and field shielding conductor 121, which can be separately arranged. For example, gate conductor 120 can be at least located on gate dielectric layer 111, and field shielding conductor 121 may be at least located on voltage-blocking layer 113. In one example, gate conductor 120 can be located on gate dielectric layer 111 and a portion of buffer field plate 112, and field shielding conductor 121 may be located on a portion of voltage-blocking layer 113 and a portion of buffer field plate 112. In other examples, gate conductor 120 may only be located on gate dielectric layer 111, may extend from gate dielectric layer 111 to buffer field plate 112, or may extend from gate dielectric layer 111 to voltage-blocking layer 113.

In other examples, field shielding conductor 121 may be only located on voltage-blocking layer 113, or may extend from voltage-blocking layer 113 to buffer field plate 112. For example, gate conductor 120 and field shielding conductor 121 can be made of a polysilicon material. The field shielding conductor may be set to the first doping type or the second doping type. Field shielding conductor 121 may be connected to the same potential as gate conductor 120, or separately to other potentials.

In particular embodiments, the LDMOS transistor can include ultra-thin gate dielectric layer 111, which can result in a low threshold voltage for the transistor, which may reduce the energy required by low-threshold power modules/circuits in driving power integrated circuits and increase the switching frequencies of the low-threshold power modules. Moreover, the reduced threshold voltage can increase the reverse surface channel current of the transistor, which in turn can suppress the body reverse recovery current flowing through the well and body regions. As a result, power loss in the power stage driver during high-frequency switching can be significantly reduced, while the reverse recovery loss of the transistor may also be minimized.

Buffer field plate 112 can be regarded as an extension of the gate dielectric layer and may have a thickness greater than that of the gate dielectric layer, thereby reducing the electric field intensity experienced by the gate dielectric layer near the drain region. This can help to shorten the length of the gate dielectric layer, decrease the charge required to turn on the transistor, and suppress the tunneling current in the gate dielectric layer when the transistor operates under high voltage. In addition, the lower surface of the buffer field plate can be coplanar with the lower surface of the gate dielectric layer, and this may result in a shorter surface current path of the transistor, which can further reduce the transistor's specific on-resistance.

Voltage-blocking layer 113 can be formed as an oxide layer thicker than buffer field plate 112, and may protrude inwardly into the semiconductor region, thereby lengthening the surface current path in the transistor's high-voltage region and enhancing its breakdown voltage capability. Voltage-blocking layer 113, together with the field shielding conductor located above it and electrically isolated from the gate electrode, as well as the drift region positioned below, can cooperatively enhance the transistor's breakdown voltage, reduce voltage coupling from the drain to the gate stage, lower voltage coupling loss, and effectively decrease the transistor's specific on-resistance.

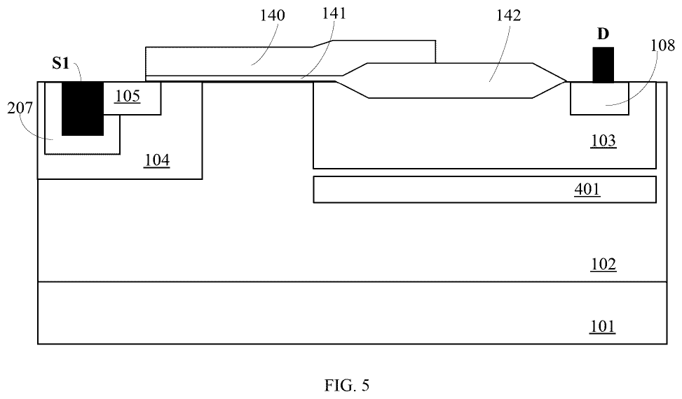

Referring now to FIG. 5, shown is a cross-sectional view of a fifth example LDMOS transistor, in accordance with embodiments of the present invention. In this particular example, RESURF region 401 of the second doping type can be arranged below drift region 103 of the first doping type to deplete each other with drift region 103. This can reduce the surface electric field between the gate and drain of the transistor, and may improve the breakdown voltage of the transistor. RESURF region 401 may be in contact with body region 104, or may be separated from the body region. A spacing between drift region 103 and RESURF region 401 can be greater than or equal to 0. Alternatively, drift region 103 and RESURF region 401 may also be arranged left and right, or RESURF region 401 can surround drift region 103, as just a few examples. The positional relationship between drift region 103 and RESURF region 401 may be adjusted as needed for the specific application.

As an example, one drift region 103 and one RESURF region 401 can respectively be provided. In another example, a plurality of drift regions 103 and a plurality of RESURF regions 401 may be provided. In yet another example, drift region 103 can include a plurality of first doped regions that are separately arranged, and RESURF region 401 can include a plurality of second doped regions that are separately arranged. For example, the plurality of first doped regions can be separately arranged in a lateral direction, the plurality of second doped regions can be separately arranged in a lateral direction, and the second doped regions may be located below the first doped regions. For example, one second doped region can be arranged below each first doped region. A spacing between adjacent first doped regions and a width of each first doped region may be adjusted according to particular requirements, and a spacing between adjacent second doped regions and a width of each first doped region may also be adjusted according to particular requirements.

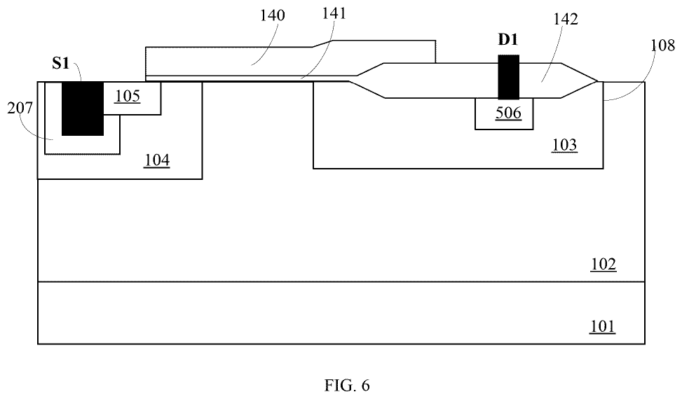

Referring now to FIG. 6, shown is a cross-sectional view of a sixth example LDMOS transistor, in accordance with embodiments of the present invention. In this particular example, drain region 506 can be located below voltage-blocking layer 143, drain electrode D1 can penetrate through voltage-blocking layer 142 to be in contact with drain region 506. For example, drain region 506 may be aligned with a side of voltage-blocking layer 142 away from gate dielectric layer 141. In another example, the LDMOS transistor can also include a shallow isolation trench located below voltage-blocking layer 142. The shallow isolation trench can be disposed between the source region and the drain region. As another example, the drain region may be disposed below the voltage-blocking layer, and the formation of a metal silicide barrier layer in the drain region can be omitted, in order to reduce the size of the LDMOS transistor.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A laterally-diffused metal-oxide-semiconductor (LDMOS) transistor, comprising:
a) a semiconductor region;
b) a body region of a second doping type, wherein the body region extends from an upper surface of the semiconductor region to an interior of the semiconductor region;
c) a source region of a first doping type and a body contact region of the second doping type, wherein the source region extends from an upper surface of the body region to an interior of the body region;
d) a drain region of the first doping type, wherein the drain region is located in the semiconductor region;
e) a source electrode that is in contact with the body contact region and the source region; and
f) wherein a junction depth of the body contact region is greater than a junction depth of the source region.

2. The LDMOS transistor of claim 1, wherein the body contact region surrounds at least a portion of a lower surface of the source region.

3. The LDMOS transistor of claim 1, wherein the source electrode is located on upper surfaces of the source region and the body contact region.

4. The LDMOS transistor of claim 1, wherein the source electrode extends from an upper surface of the body contact region to an interior of the body contact region.

5. The LDMOS transistor of claim 4, wherein the source electrode extends to a depth in the body contact region that is greater than the junction depth of the source region.

6. The LDMOS transistor of claim 4, wherein the source electrode is in contact with a side surface of the source region.

7. The LDMOS transistor of claim 4, wherein the source electrode comprises a trench located in the body contact region and a conductive material filled in the trench.

8. The LDMOS transistor of claim 4, wherein a width of the body contact region along a direction from the source region to the drain region is greater than a width of the source electrode.

9. The LDMOS transistor of claim 1, further comprising:
a) a gate dielectric layer adjacent to the source region, wherein the gate dielectric layer is located on the upper surface of the semiconductor region; and
b) a voltage-blocking layer adjacent to the drain region, wherein the voltage-blocking layer is located on the semiconductor region.

10. The LDMOS transistor of claim 9, further comprising:
a) a buffer field plate disposed between the gate dielectric layer and the voltage-blocking layer, wherein the buffer field plate is located on the upper surface of the semiconductor region; and
b) wherein a thickness of the voltage-blocking layer is greater than a thickness of the buffer field plate, and the thickness of the buffer field plate is greater than a thickness of the gate dielectric layer.

11. The LDMOS transistor of claim 9, further comprising a drift region of the first doping type located in the semiconductor region, wherein the drift region is located below at least the voltage-blocking layer.

12. The LDMOS transistor of claim 9, wherein the voltage-blocking layer protrudes toward the interior of the semiconductor region.

13. The LDMOS transistor of claim 10, wherein a lower surface of the buffer field plate and a lower surface of the gate dielectric layer are located on a same plane that is parallel to a direction from the source region to the drain region.

14. The LDMOS transistor of claim 10, wherein a lower surface of the buffer field plate and a lower surface of the gate dielectric layer are higher than a lower surface of the voltage-blocking layer.

15. The LDMOS transistor of claim 10, wherein the thickness of the gate dielectric layer is set to be in a range of from 0.95 nm to 9.5 nm.

16. The LDMOS transistor of claim 10, further comprising a gate conductor located on at least the gate dielectric layer.

17. The LDMOS transistor of claim 10, further comprising a field shielding conductor located on at least the voltage-blocking layer.

18. The LDMOS transistor of claim 11, further comprising a reduced surface field (RESURF) region of the second doping type located in the semiconductor region, wherein the RESURF region and the drift region are mutually depleted.

19. The LDMOS transistor of claim 9, further comprising a drain electrode that extends through the voltage-blocking layer to the drain region.

20. The LDMOS transistor of claim 9, further comprising a shallow trench isolation structure located below the voltage-blocking layer.
